(19) United States
(12) Patent Application Publication
(10) Pub. No.: US 2015/0263258 A1
(43) Pub. Date: Sep. 17, 2015

(54) THERMOELECTRIC CONVERSION ELEMENT

(71) Applicant: Kabushiki Kaisha Toshiba, Minato-ku (JP)

(72) Inventors: Masaki KADO, Kamakura (JP); Yuuzo KAMIGUCHI, Yokohama (JP); Hiromi YUASA, Kawasaki (JP)

(73) Assignee: Kabushiki Kaisha Toshiba, Minato-ku (JP)

(21) Appl. No.: 14/602,713

(22) Filed: Jan. 22, 2015

(30) Foreign Application Priority Data
Mar. 11, 2014 (JP) 2014-047304

(51) Int. Cl. H01L 37/00

(52) U.S. Cl. CPC H01L 37/00

(57) ABSTRACT

A thermoelectric conversion element comprises a substrate, an insulating ferromagnetic layer, and a nonmagnetic metal layer. The insulating ferromagnetic layer is formed upwardly on the substrate and has a magnetization fixed in a certain direction. At least one trench is formed on a surface of this insulating ferromagnetic layer so as to extend in a direction along the surface of the insulating ferromagnetic layer. The nonmagnetic metal layer is formed conforming to a shape of the trench, upwardly on the insulating ferromagnetic layer including on a wall surface of the trench.

### CROSS REFERENCE TO RELATED APPLICATIONS

This application is based on and claims the benefit of priority from prior Japanese Patent Application No. 2014-47304, filed on Mar. 11, 2014, the entire contents of which are incorporated herein by reference.

### FIELD

Embodiments described herein relate to a thermoelectric conversion element.

### BACKGROUND

A thermoelectric conversion element that utilizes a spin Seebeck effect to convert heat into a voltage, is already known. When a temperature gradient ΔT is applied to a ferromagnetic layer, a spin pressure which is a difference between an up-spin flow and a down-spin flow, is generated. This phenomenon is called the spin Seebeck effect.

A spin pressure in a spin flow generating layer is provided as a spin flow Jspin. The spin flow Jspin is a flow of a difference between an up-spin flow and a down-spin flow, and is not a flow of charge. When the spin flow Jspin flows, an electromotive force E is generated in a direction orthogonal to the spin flow Jspin and a magnetization, by an inverse spin Hall effect, and a current which is a flow of charge, flows. As a result, electricity is generated.

However, efficiency of a current thermoelectric conversion element employing the spin Seebeck effect is not sufficient, and in order to be employed as a practical energy source, a further improvement in thermoelectric conversion efficiency is required.

### BRIEF DESCRIPTION OF THE DRAWINGS

FIG. 1 is a schematic perspective view showing a basic configuration and operation of a thermoelectric conversion element of a first embodiment.

FIG. 2 is a schematic perspective view showing a specific configuration and operation of the thermoelectric conversion element of the first embodiment.

FIG. 3 is a schematic perspective view showing a specific configuration and operation of a thermoelectric conversion element of a second embodiment.

FIG. 4 is a schematic perspective view showing a specific configuration and operation of the thermoelectric conversion element of the second embodiment.

FIG. 5 is a schematic perspective view showing a specific configuration and operation of the thermoelectric conversion element of the second embodiment.

FIG. 6 is a schematic perspective view showing a specific configuration and operation of a thermoelectric conversion element of a third embodiment.

FIG. 7 is a schematic perspective view showing a specific configuration and operation of the thermoelectric conversion element of the third embodiment.

FIG. 8 is a schematic perspective view showing a specific configuration and operation of the thermoelectric conversion element of the third embodiment.

FIG. 9 is a schematic perspective view showing a specific configuration and operation of a thermoelectric conversion element of a fourth embodiment.

FIG. 10 is a schematic perspective view showing a specific configuration and operation of the thermoelectric conversion element of the fourth embodiment.

FIG. 11 is a schematic perspective view showing a specific configuration and operation of the thermoelectric conversion element of the fourth embodiment.

FIG. 12 is a cross-sectional TEM image of the thermoelectric conversion element of the fourth embodiment, and a cross-sectional TEM image of a thermoelectric conversion element in which a surface of an insulating ferromagnetic layer is planar.

FIG. 13 is a graph showing a relationship between temperature difference and thermal electromotive force of the thermoelectric conversion element of the fourth embodiment.

FIG. 14 is a table showing thermoelectric conversion characteristics of the thermoelectric conversion element of the fourth embodiment.

### DETAILED DESCRIPTION

A thermoelectric conversion element according to an embodiment described below comprises a substrate, an insulating ferromagnetic layer, and a nonmagnetic metal layer. The insulating ferromagnetic layer is formed upwardly on the substrate and has a magnetization fixed in a certain direction. At least one trench is formed on a surface of this insulating ferromagnetic layer so as to extend in a first direction. The nonmagnetic metal layer is formed conforming to a shape of the trench, upwardly on the insulating ferromagnetic layer including on a wall surface of the trench.

Moreover, a thermoelectric conversion element according to another embodiment described below comprises a substrate, an insulating ferromagnetic layer, and a nonmagnetic metal layer. At least one trench is formed on a surface of the substrate so as to extend in a first direction. The insulating ferromagnetic layer is formed having a shape conforming to a shape of the trench, upwardly on the surface of the substrate including on a wall surface of the trench, and has a magnetization fixed in a second direction intersecting with a stacking direction. Moreover, the nonmagnetic metal layer is formed upwardly on a surface of the insulating ferromagnetic layer and is formed so as to have a shape that conforms to the shape of the trench.

Next, thermoelectric conversion elements according to embodiments will be described in detail with reference to the drawings.

### First Embodiment

A configuration of a thermoelectric conversion element according to a first embodiment will be described with reference to the drawings.

[Basic Configuration]

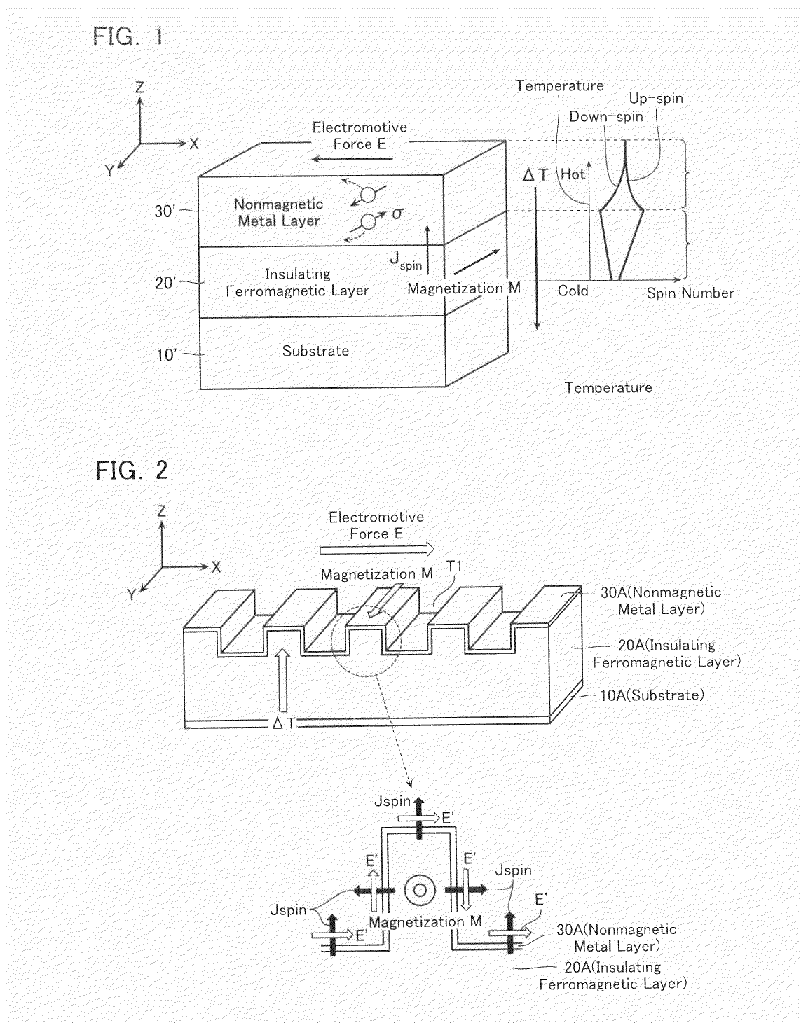

First, a basic configuration and operation of the thermoelectric conversion element according to the first embodiment will be described with reference to FIG. 1. This thermoelectric conversion element of the first embodiment comprises an insulating ferromagnetic layer 20′ and a nonmagnetic metal layer 30′ stacked along a Z direction on a substrate 10′, the Z direction being a stacking direction (direction normal to a surface of the substrate 10′). The insulating ferromagnetic layer 20′ is provided with, for example, a magnetization M that conforms to a Y direction intersecting with the Z direction. Note that the substrate 10′, the insulating ferromagnetic layer 20′, and the nonmagnetic metal layer 30′ may contact each other directly. In particular, the insulating ferromagnetic layer 20′ has insulation properties, hence there is no problem even if it contacts the nonmagnetic metal layer 30′ directly. However, it is also possible to adopt a configuration that sandwiches between these layers a film not preventing later-mentioned physical interaction between the layers, such as a buffer film or adhesive film.

After performing a surface cleaning on the substrate 10′, the insulating ferromagnetic layer 20′ and the nonmagnetic metal layer 30′ can be deposited by employing the likes of: a dry process such as a sputtering method, a evaporation method, and a CVD method; a wet process such as an electroplating method or an electroless plating method; and a coating method.

With regard to the substrate 10′, its material or the like is not limited to specific ones, unless the substrate 10′ hinders a function or change a composition of the insulating ferromagnetic layer 20′ or nonmagnetic metal layer 30′ formed as upper layers of the substrate 10′. However, in order to make it possible for the thermoelectric conversion element to utilize all heat-generating surfaces to generate electricity in a comparatively large surface area, it is preferable to employ a flexible insulator as the substrate 10′. Specifically, a substrate having a flexibility of a Young's modulus of 10 or less, is desirable. Specifically, the substrate 10′ may comprise any of a polyimide, polypropylene, nylon, polyester, parylene, rubber, biaxial stretching polyethylene 2,6-naphthalate, modified polyamide, and so on, or from a lamination of those materials.

In addition, the insulating ferromagnetic layer 20′ may comprise any of garnet ferrite, spinel ferrite, or hexagonal ferrite, or from a lamination of those materials. Moreover, the nonmagnetic metal layer 30′ can comprise any of platinum (Pt), gold (Au), iridium (Ir), nickel (Ni), tantalum (Ta), tungsten (W), or chromium (Cr), or may be formed from an alloy of these.

Next, operation of this thermoelectric conversion element will be described. When a temperature gradient ΔT is provided along the Z direction, that is, the stacking direction, of this thermoelectric conversion element, a spin pressure which is a difference between an up-spin flow and a down-spin flow, is generated (a spin Seebeck effect). This spin pressure is provided as a spin flow Jspin in the adjacent nonmagnetic metal layer 30′. The spin flow Jspin is a flow of the difference between the up-spin flow and the down-spin flow, and is not a flow of charge. When the spin flow Jspin flows up toward the nonmagnetic metal layer 30′, an electromotive force E is generated in a direction orthogonal to the spin flow Jspin and the magnetization M (an X direction in FIG. 1), by an inverse spin Hall effect. This electromotive force E causes the thermoelectric conversion element to generate a current which is a flow of charge, and function as an electrical energy source.

Specifically, the thermoelectric conversion element of the first embodiment has a shape shown in FIG. 2 that further improves the structure of FIG. 1. This thermoelectric conversion element of FIG. 2 is the same as the thermoelectric conversion element of FIG. 1 in the point of comprising a substrate 10A, an insulating ferromagnetic layer 20A, and a nonmagnetic metal layer 30A stacked in the Z direction. Materials of the substrate 10A, the insulating ferromagnetic layer 20A, and the nonmagnetic metal layer 30A may be identical to those of the previously mentioned substrate 10′, insulating ferromagnetic layer 20′, and nonmagnetic metal layer 30′. Moreover, the insulating ferromagnetic layer 20A has the magnetization M extending in the Y direction as an example.

The thermoelectric conversion element of FIG. 2 has a plurality of stripe shaped trenches T1 extending in the Y direction on a surface of the insulating ferromagnetic layer 20A. Moreover, the nonmagnetic metal layer 30A is formed conforming to a shape of the trench T1, on the surface of the insulating ferromagnetic layer 20A including on a wall surface (sidewall and bottom surface) of this trench T1. The trench T1 can be formed by, for example, mask formation by photolithography or nanoimprint lithography, and dry etching.

When the temperature gradient ΔT along the Z direction, that is, the stacking direction, is applied to the thermoelectric conversion element having this kind of structure of FIG. 2, a spin flow Jspin′ intersecting with each of surfaces (left side surface, upper surface, right side surface, and bottom surface) of the trench T1 is generated by the spin Seebeck effect. The spin flow Jspin′ preferably comprises only a component Jspin perpendicular to each of the surfaces of the trench T1, but may include another component. As a result, an electromotive force E′ generated in a direction orthogonal to both of the magnetization M and the spin flow Jspin by the inverse spin Hall effect is respectively generated at each of the surfaces (right side surface, bottom surface, left side surface, and upper surface) of the trench T1. Moreover, the electromotive force E in the thermoelectric conversion element overall is generated as a sum of the electromotive force E′ at each of these surfaces.

In this way, in the thermoelectric conversion element according to the first embodiment (FIG. 2), an area of an interface between the insulating ferromagnetic layer and the nonmagnetic metal layer per unit area of an XY plane is increased by an amount of side surfaces of the trench, compared to the thermoelectric conversion element of FIG. 1 whose surface is planar. Due to the area of the interface being increased, an amount of electricity generated per unit area (generated electricity density) becomes larger, and as a result, the electromotive force E in the thermoelectric conversion element overall also increases. Therefore, the thermoelectric conversion element of the first embodiment (FIG. 2) enables the amount of generated electricity to be improved.

In the thermoelectric conversion element of FIG. 2, a trench T1 having a rectangular shape as a cross-sectional shape of the trench was shown, but the shape of the trench T1 is not limited to this rectangular shape, and may be, for example, a trapezoidal shape, a V shape, a U shape, or an arc shape. In addition, it is also possible to adopt a trench having a concave curve. Alternatively, there may be a combination of trenches of these various shapes. Note that from the viewpoint of stability of trench formation and uniform deposition of the nonmagnetic metal layer, it is desirable that a width (X direction) of the trench T1 is 30 nm or more. Furthermore, from the viewpoint of improvement of generated electricity density, it is desirable that a ratio of height to width (Z/X ratio) of the trench T1 is larger than 1.

Moreover, in the above-described example, a direction of the magnetization M of the insulating ferromagnetic layer 20A was described as being the Y direction and matching with a longer direction of the trench T1, but the direction of the magnetization M need not necessarily match that of the trench T1. Even when not matched, the above-mentioned effects are obtained with respect to a component in the Y direction of that magnetization M.

### Second Embodiment

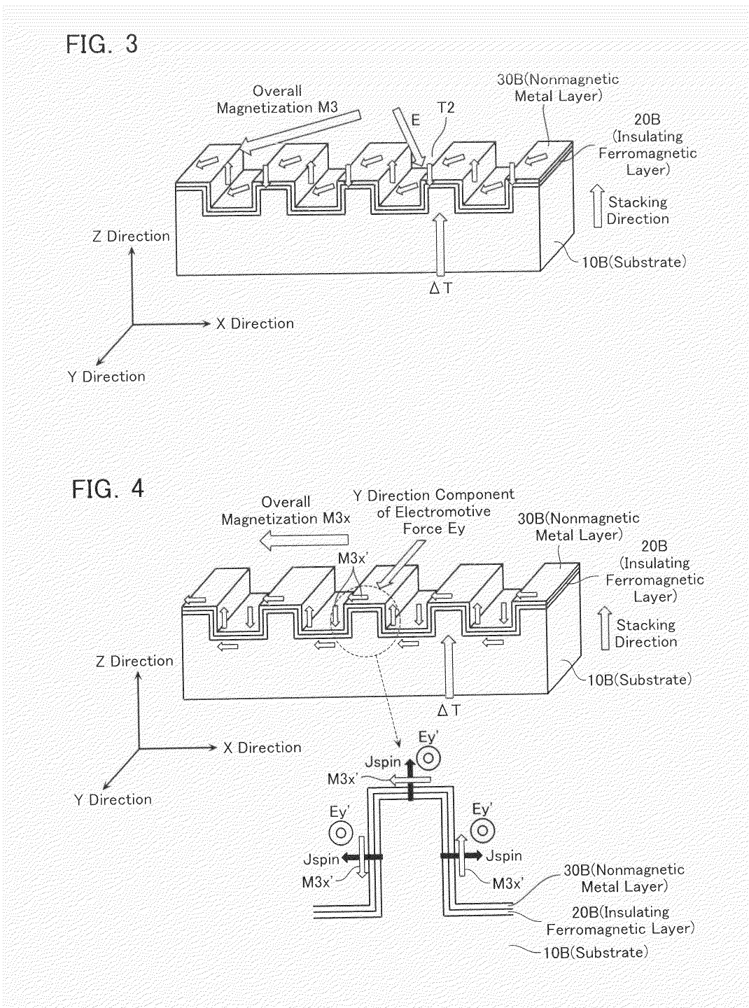

Next, a thermoelectric conversion element according to a second embodiment will be described with reference to FIGS. 3 to 5.

As shown in FIG. 3, this thermoelectric conversion element of the second embodiment is the same as the thermoelectric conversion element of the first embodiment in the point of comprising a substrate 10B, an insulating ferromagnetic layer 20B, and a nonmagnetic metal layer 30B stacked in the Z direction. Materials of the substrate 10B, the insulating ferromagnetic layer 20B, and the nonmagnetic metal layer 30B may be identical to those of the substrate 10A, the insulating ferromagnetic layer 20A, and the nonmagnetic metal layer 30A of the first embodiment.

However, this thermoelectric conversion element of the second embodiment has in a surface of the substrate 10B a stripe shaped trench T2, for example, that extends in the Y direction as a longer direction. This point differs from the first embodiment in which the trench T1 is formed in the surface of the insulating ferromagnetic layer 20A. Moreover, the insulating ferromagnetic layer 20B and the nonmagnetic metal layer 30B are sequentially deposited on the surface of the substrate 10B including on an upper surface, bottom surface, and side surfaces of this trench T2, so as to have a shape that conforms to the trench T2.

The trench T2 of the substrate 10B may be formed by, for example, dry etching employing a resist mask formed by photolithography or nanoimprint lithography, or press formation. In deposition of the insulating ferromagnetic layer 20B and the nonmagnetic metal layer 30B, for example, a dry process such as a sputtering method, evaporation method, or CVD method, a wet process such as an electroplating method or electroless plating method, or a coating method can be employed.

In this thermoelectric conversion element of the second embodiment, the insulating ferromagnetic layer 20B has a magnetization that locally conforms to a shape of the trench T2 of the substrate 10B, and the insulating ferromagnetic layer 20B as a whole has a magnetization M3 that is fixed in a direction intersecting with the Z direction, that is, the stacking direction. When the temperature gradient ΔT is applied in the Z direction, that is, the stacking direction, of this thermoelectric conversion element, the electromotive force E is generated in a direction orthogonal to both of the magnetization M3 and the temperature gradient ΔT.

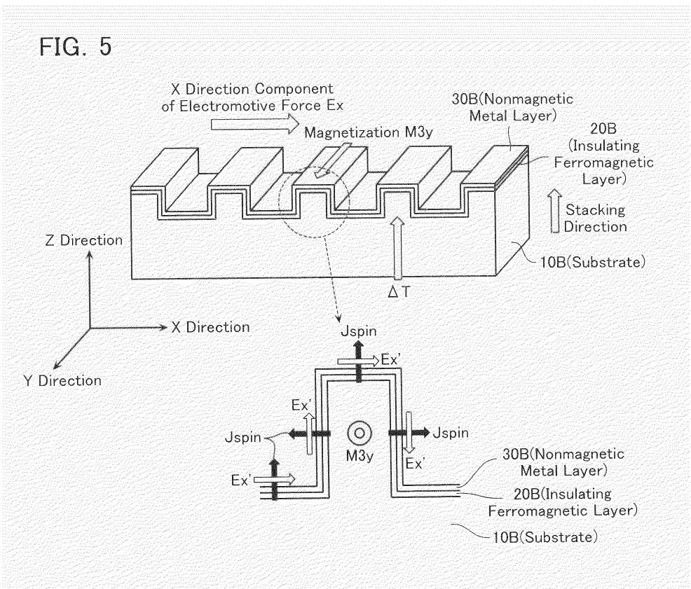

In order to make it easy to understand a mechanism of generation of the electromotive force E in this case, FIGS. 4 and 5 are described dividing the magnetization M3 into a magnetization M3x along an X axis direction and a magnetization M3y along a Y axis direction. The magnetizations M3x and M3y respectively generate electromotive forces Ey and Ex, and the sum of these electromotive forces Ey and Ex is the overall electromotive force E.

As shown in FIG. 4, the magnetization M3x can be divided into magnetizations M3x′ conforming to a surface of the insulating ferromagnetic layer 20B that locally has unevenness. When the temperature gradient ΔT is applied along the Z direction in this situation, the spin flow Jspin is generated in a direction orthogonal to each of surfaces (upper surface, bottom surface, left side surface, and right side surface) of the trench T2 by the spin Seebeck effect due to the temperature gradient ΔT. An electromotive force Ey′ is generated along the Y direction of the trench T2, based on the inverse spin Hall effect, in a direction orthogonal to this spin flow Jspin and the magnetizations M3x′ conforming to each of the surfaces of the trench T2. Such an electromotive force Ey′ is generated in each of the surfaces of the trench T2. Therefore, the electromotive force Ey generated based on the magnetization M3x is generated based on a plurality of electromotive forces Ey′ that are generated in parallel.

Moreover, as shown in FIG. 5, the electromotive force Ex is generated in the X direction based on the magnetization M3y along the Y axis direction. That is, when the temperature gradient ΔT is applied along the Z direction in a state where the magnetization M3y in the Y axis direction is applied, the spin flow Jspin is generated in a direction orthogonal to each of the surfaces (upper surface, bottom surface, left side surface, and right side surface) of the trench T2 by the spin Seebeck effect due to the temperature gradient ΔT. An electromotive force Ex′ is generated at each of the surfaces of the trench T2 based on the inverse spin Hall effect, in a direction orthogonal to this spin flow Jspin and the magnetization M3y, that is, in a direction conforming to a film surface of the nonmagnetic metal layer 30B. A sum of the electromotive forces Ex′ at each of these surfaces is the electromotive force Ex. Moreover, the sum of the above-mentioned electromotive force Ey and this electromotive force Ex is the overall electromotive force E of the thermoelectric conversion element of the second embodiment. Electric power based on this electromotive force E can be taken out by connecting a pair of electrodes along a direction intersecting with the magnetization M3, on the nonmagnetic metal layer 30B.

Note that in the second embodiment, a direction of the magnetization M may be any direction, and it does not matter what a ratio of an X axis direction component and a Y axis direction component is. One of the two direction may be zero. In this case, only one of the effects shown in FIG. 4 or 5 occurs.

In this thermoelectric conversion element of the second embodiment also, the area of the interface between the insulating ferromagnetic layer 20B and the nonmagnetic metal layer 30B per unit area of the XY plane is increased and the generated electricity density is proportionately increased, compared to in the planar thermoelectric conversion element of FIG. 1.

### Third Embodiment

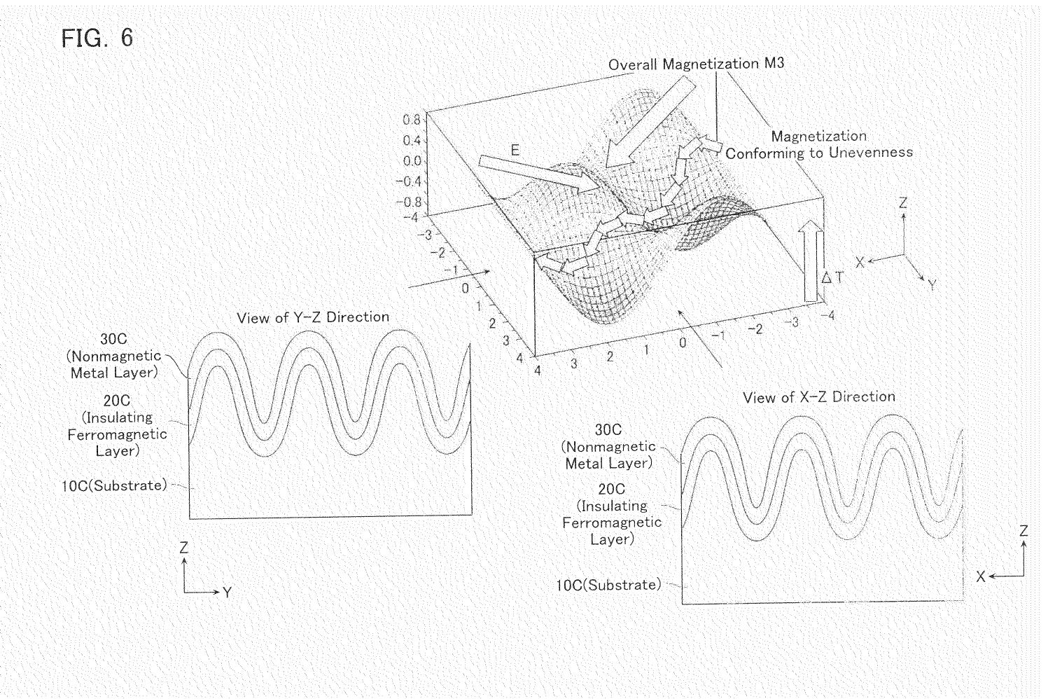

Next, a thermoelectric conversion element according to a third embodiment will be described with reference to FIGS. 6 to 8.

As shown in FIG. 6, this thermoelectric conversion element of the third embodiment is the same as the thermoelectric conversion element of the second embodiment in the point of comprising a substrate 10C, an insulating ferromagnetic layer 20C, and a nonmagnetic metal layer 30C stacked in the Z direction, and in that the insulating ferromagnetic layer 20C and the nonmagnetic metal layer 30C have a shape conforming to the trench of the substrate 10C. Materials of the substrate 10C, the insulating ferromagnetic layer 20C, and the nonmagnetic metal layer 30C may be identical to those of the substrate 10B, the insulating ferromagnetic layer 20B, and the nonmagnetic metal layer 30B of the second embodiment.

However, this thermoelectric conversion element of the third embodiment comprises, for example, a uniform sine-wave shaped unevenness in a surface of the substrate 10C. This point differs from the second embodiment in which the rectangular shaped trench is formed in the surface of the substrate 10B. Moreover, the substrate 10C is formed not only having the sine-wave shaped unevenness along the X direction, but also having a sine-wave shaped unevenness along the Y direction. A concave portion of this sine-wave shaped unevenness corresponds to the trench T2 of the second embodiment. In other words, in this third embodiment, a trench of the substrate 10C is formed so as to extend in both of the X direction and the Y direction. Moreover, the insulating ferromagnetic layer 20C and the nonmagnetic metal layer 30C are sequentially deposited on the surface of the substrate 10C including this unevenness, so as to have a shape that conforms to the unevenness.

The unevenness of the substrate 10C may be formed by, for example: dry etching employing a resist mask formed by photolithography or nanoimprint lithography; or press formation. Moreover, the unevenness of the substrate 10C may be formed by performing anisotropic etching to the substrate 10C. In addition, a porous material and a self-assembled material such as a diblock copolymer or fractal structure polymer and so on may be used for the substrate 10C. Furthermore, the unevenness of the substrate 10C may be formed by implanting a carbon nanotube in the substrate 10C. In deposition of the insulating ferromagnetic layer 20C and the nonmagnetic metal layer 30C, for example, a dry process such as a sputtering method, evaporation method, or CVD method, a wet process such as an electroplating method or electroless plating method, or a coating method can be employed.

In this thermoelectric conversion element of the third embodiment, the insulating ferromagnetic layer 20C has a magnetization that locally conforms to a shape of the unevenness of the substrate 10C, and the insulating ferromagnetic layer 20C as a whole has a magnetization that is fixed in a direction intersecting with the Z direction, that is, the stacking direction. When the temperature gradient ΔT is applied in the Z direction, that is, the stacking direction, of this thermoelectric conversion element, the electromotive force E is generated in a direction orthogonal to both of the magnetization and the temperature gradient ΔT.

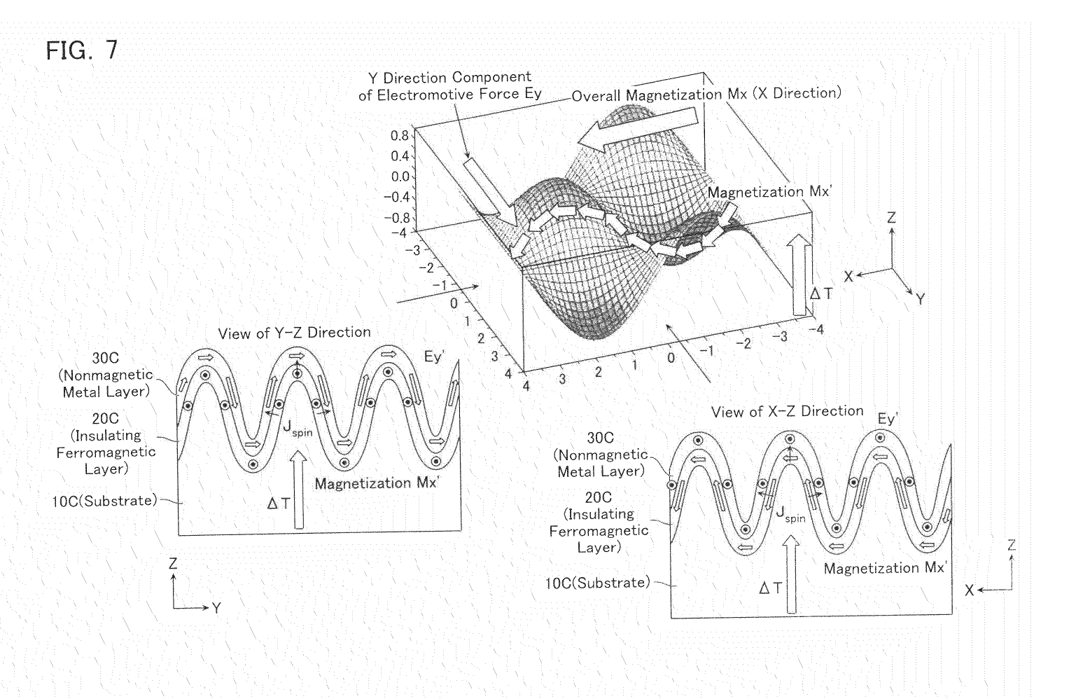

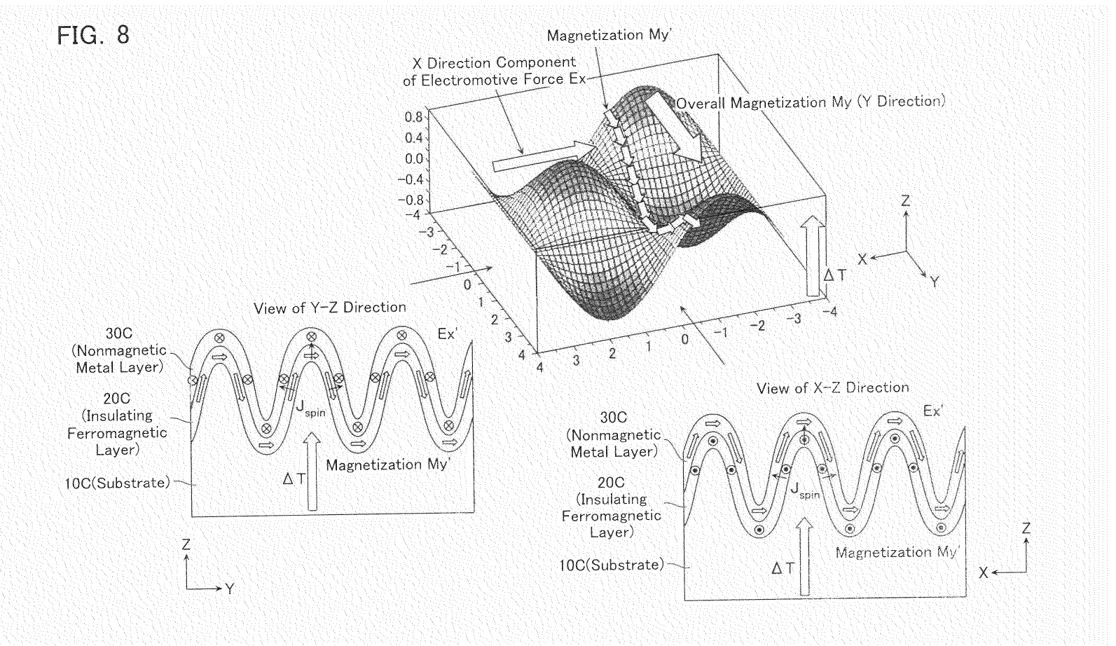

In order to make it easy to understand a mechanism of generation of the electromotive force E in this case, FIGS. 7 and 8 are described dividing the magnetization into a magnetization Mx along an X axis direction and a magnetization My along a Y axis direction. The magnetization Mx and the magnetization My respectively generate electromotive forces Ey and Ex, and the sum of these electromotive forces Ey and Ex is the overall electromotive force E.

As shown in FIG. 7, the overall magnetization Mx can be locally divided into magnetizations Mx′ conforming to a surface of the insulating ferromagnetic layer 20C that has the unevenness. When the temperature gradient ΔT is applied along the Z direction in this situation, the spin flow Jspin is generated in a normal direction to each place of the unevenness by the spin Seebeck effect due to the temperature gradient ΔT. An electromotive force Ey′ is generated along the Y direction of the unevenness, based on the inverse spin Hall effect, in a direction orthogonal to this spin flow Jspin and the magnetizations Mx′ conforming to the surface of the unevenness. Such an electromotive force Ey′ is generated in each place of the unevenness. Therefore, the electromotive force Ey generated based on the magnetization Mx is generated as a sum of the electromotive forces Ey′ in the Y direction.

Moreover, as shown in FIG. 8, the overall magnetization My can be locally divided into magnetizations My′ conforming to the surface of the insulating ferromagnetic layer 20C that has the unevenness. When the temperature gradient ΔT is applied along the Z direction in this situation, the spin flow Jspin is generated in a normal direction to each place of the unevenness by the spin Seebeck effect due to the temperature gradient ΔT. An electromotive force Ex′ is generated at each place of the unevenness based on the inverse spin Hall effect, in a direction orthogonal to this spin flow Jspin and the magnetization My′, that is, in a direction conforming to a film surface of the nonmagnetic metal layer 30C. A sum of the electromotive forces Ex′ in the X direction is the electromotive force Ex. Moreover, the sum of the above-mentioned electromotive force Ey and this electromotive force Ex is the overall electromotive force E of the thermoelectric conversion element of the third embodiment. Electric power based on this electromotive force E can be taken out by connecting a pair of electrodes along a direction intersecting with the magnetization, on the nonmagnetic metal layer 30C.

Note that in the third embodiment, a direction of the magnetization may be any direction, and it does not matter what a ratio of an X axis direction component and a Y axis direction component is. One of the two direction may be zero. In this case, only one of the effects shown in FIG. 7 or 8 occurs.

In this thermoelectric conversion element of the third embodiment also, the area of the interface between the insulating ferromagnetic layer 20C and the nonmagnetic metal layer 30C per unit area of the XY plane is increased and the generated electricity density is proportionately increased, compared to in the planar thermoelectric conversion element of FIG. 1.

### Fourth Embodiment

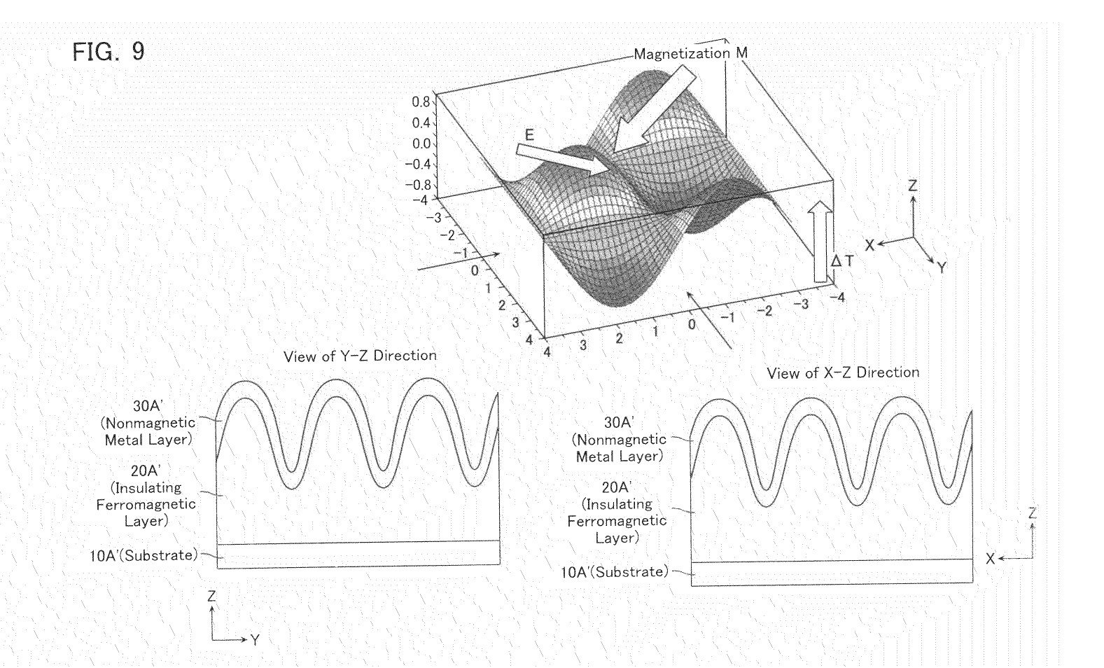

Next, a thermoelectric conversion element according to a fourth embodiment will be described with reference to FIGS. 9 to 11.

As shown in FIG. 9, this thermoelectric conversion element of the fourth embodiment is the same as the thermoelectric conversion element of the first embodiment in the point of comprising a substrate 10A′, an insulating ferromagnetic layer 20A′, and a nonmagnetic metal layer 30A′ stacked in the Z direction, and in that the nonmagnetic metal layer 30A′ has a shape conforming to a trench of the insulating ferromagnetic layer 20A′. Materials of the substrate 10A′, the insulating ferromagnetic layer 20A′, and the nonmagnetic metal layer 30A′ may be identical to those of the substrate 10A, the insulating ferromagnetic layer 20A, and the nonmagnetic metal layer 30A of the first embodiment.

However, this thermoelectric conversion element of the fourth embodiment comprises, for example, a uniform sine-wave shaped unevenness in a surface of the insulating ferromagnetic layer 20A′. This point differs from the first embodiment in which the rectangular shaped trench is formed in the surface of the insulating ferromagnetic layer 20A. Moreover, the nonmagnetic metal layer 30A′ is deposited on the surface of the insulating ferromagnetic layer 20A′ including this unevenness, so as to have a shape that conforms to the unevenness.

The unevenness of the insulating ferromagnetic layer 20A′ may be formed by, for example, dry etching employing a resist mask formed by photolithography or nanoimprint lithography, or press formation. Moreover, the unevenness of the insulating ferromagnetic layer 20A′ may be formed by performing anisotropic etching to the insulating ferromagnetic layer 20A′. In addition, a porous material may be used for the insulating ferromagnetic layer 20A′. In deposition of the nonmagnetic metal layer 30A′, for example, a dry process such as a sputtering method, evaporation method, or CVD method, a wet process such as an electroplating method or electroless plating method, or a coating method can be employed.

In this thermoelectric conversion element of the fourth embodiment, the insulating ferromagnetic layer 20A′ has a magnetization M that is fixed in a direction intersecting with the Z direction, that is, the stacking direction. When the temperature gradient ΔT is applied in the Z direction, that is, the stacking direction, of this thermoelectric conversion element, the electromotive force E is generated in a direction orthogonal to both of the magnetization M and the temperature gradient ΔT.

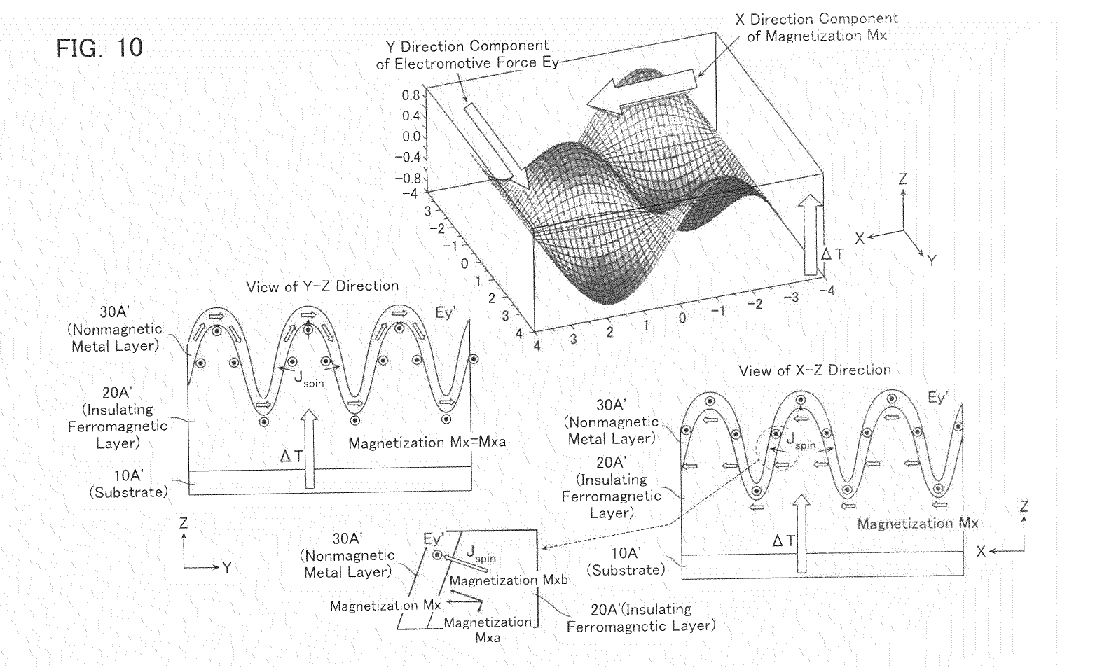

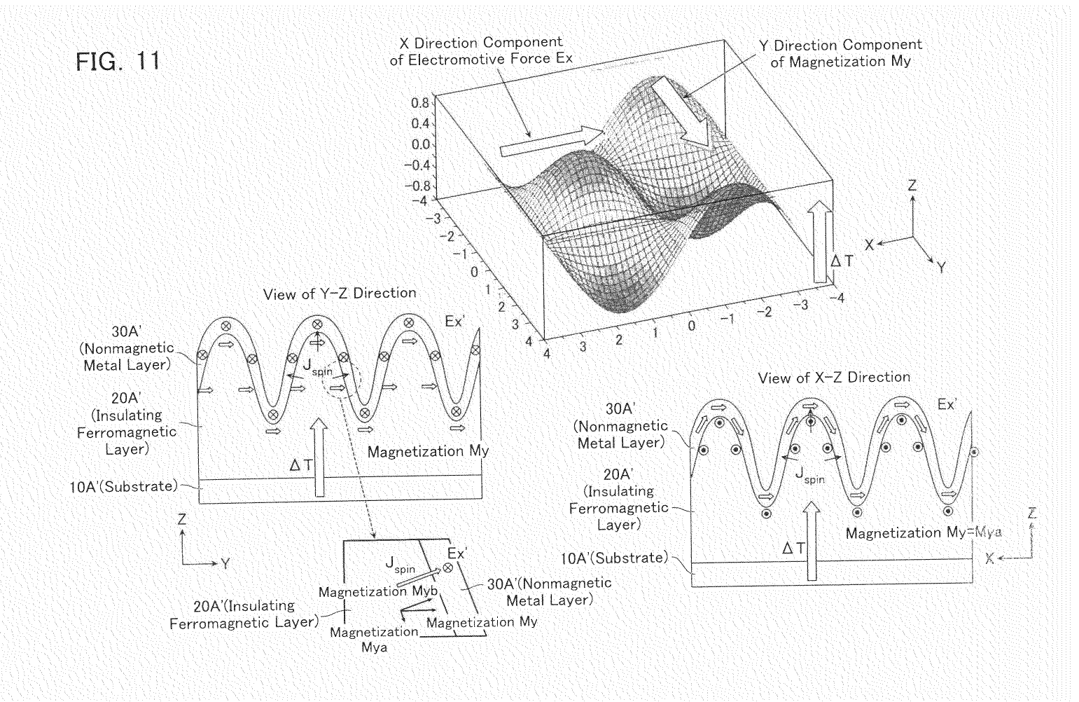

In order to make it easy to understand a mechanism of generation of the electromotive force E in this case, FIGS. 10 and 11 are described dividing the magnetization M into a magnetization Mx along an X axis direction and a magnetization My along a Y axis direction. The magnetization Mx and the magnetization My respectively generate electromotive forces Ey and Ex, and the sum of these electromotive forces Ey and Ex is the overall electromotive force E.

As shown in FIG. 10, the magnetization Mx can be divided into a magnetization Mxa which is a component parallel to, and a magnetization Mxb which is a component perpendicular to a surface of the insulating ferromagnetic layer 20A′ that locally has the unevenness. When the temperature gradient ΔT is applied along the Z direction in this situation, the spin flow Jspin is generated in a normal direction to each place of the unevenness by the spin Seebeck effect due to the temperature gradient ΔT. An electromotive force Ey′ is generated along the Y direction of the unevenness, based on the inverse spin Hall effect, in a direction orthogonal to this spin flow Jspin and the magnetization Mxa parallel to the surface of the unevenness. Such an electromotive force Ey′ is generated in each place of the unevenness. Therefore, the electromotive force Ey generated based on the magnetization Mx is generated as a sum of the electromotive forces Ey′ in the Y direction.

Moreover, as shown in FIG. 11, the electromotive force Ex is generated in the X direction based on the magnetization My along the Y axis direction. The magnetization My can be divided into a magnetization Mya which is a component parallel to, and a magnetization Myb which is a component perpendicular to the surface of the insulating ferromagnetic layer 20A′ that locally has the unevenness. When the temperature gradient ΔT is applied along the Z direction in a state where the magnetization My in the Y axis direction is applied, the spin flow Jspin is generated in a normal direction to each place of the unevenness by the spin Seebeck effect due to the temperature gradient ΔT. An electromotive force Ex′ is generated at each place based on the inverse spin Hall effect, in a direction orthogonal to this spin flow Jspin and the magnetization Mya, that is, in a direction conforming to a film surface of the nonmagnetic metal layer 30A′. A sum of the electromotive forces Ex′ in the X direction is the electromotive force Ex. Moreover, the sum of the above-mentioned electromotive force Ey and this electromotive force Ex is the overall electromotive force E of the thermoelectric conversion element of the fourth embodiment. Electric power based on this electromotive force E can be taken out by connecting a pair of electrodes along a direction intersecting with the magnetization M, on the nonmagnetic metal layer 30A′.

Note that in the fourth embodiment, a direction of the magnetization M may be any direction, and it does not matter what a ratio of an X axis direction component and a Y axis direction component is. One of the two direction may be zero. In this case, only one of the effects shown in FIG. 10 or 11 occurs.

In this thermoelectric conversion element of the fourth embodiment also, the area of the interface between the insulating ferromagnetic layer 20A′ and the nonmagnetic metal layer 30A′ per unit area of the XY plane is increased and the generated electricity density is increased proportionately to an increase of the area of the perpendicular component to the magnetization, compared to in the planar thermoelectric conversion element of FIG. 1.

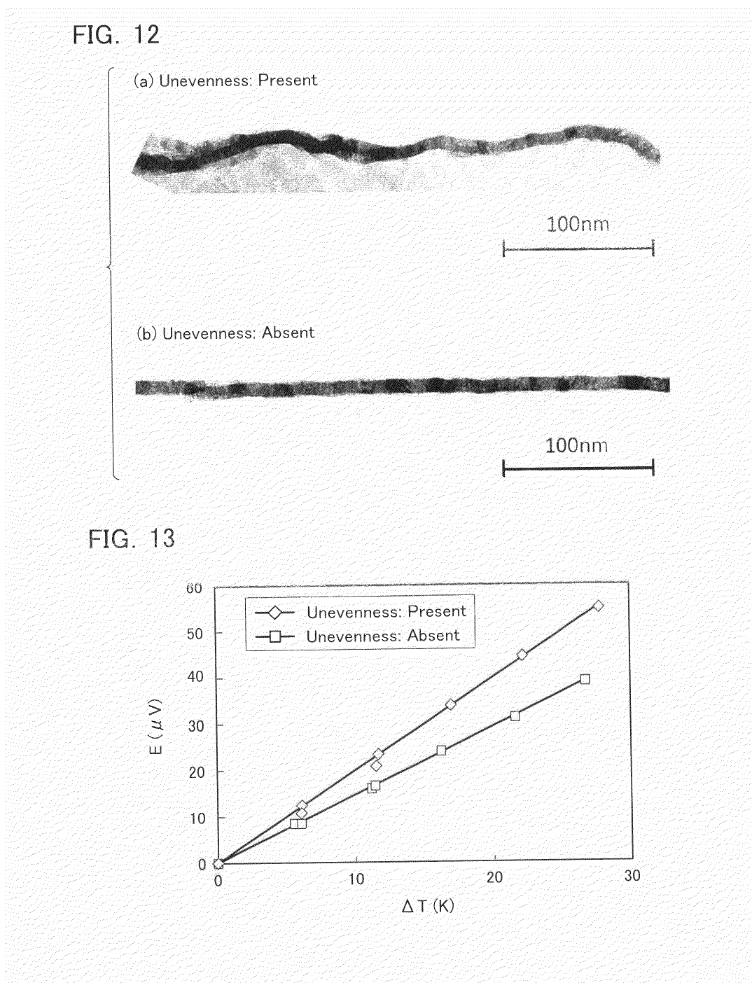

Regarding the thermoelectric conversion element of the fourth embodiment, elements were produced by the following methods and their thermal electromotive force and power generation amount were evaluated. A sintered body of yttrium iron garnet (referred to below as YIG) which is a kind of garnet ferrite is employed as the insulating ferromagnetic layer and after a surface cleaning of this YIG, platinum (Pt) acting as the nonmagnetic metal layer is deposited on an upper surface of the YIG by a sputtering method. Size of the thermoelectric conversion element in this case is length 30 mm×width 5 mm×height 2 mm, and a film thickness of Pt is 10 nm. Regarding a surface shape, the sintered body YIG surface has an unevenness of a size of about 100 nm and a height of about 20 nm, and Pt is formed so as to conform to the shape of the unevenness (FIG. 12(a)). In contrast, in a thermoelectric conversion element in which the surface of the YIG sintered body is polished and then platinum (Pt) deposited by a similar process, the surface shape becomes planar without the unevenness, as in FIG. 12(b).

A relationship between a temperature difference ΔT applied in an upper/under surface direction and the thermal electromotive force E about these thermoelectric conversion elements is shown in FIG. 13. In both the thermoelectric conversion element with the unevenness and the thermoelectric conversion element without the unevenness, the thermal electromotive force E is proportional to the temperature difference ΔT, and when compared at the same temperature difference ΔT, the thermal electromotive force E obtained for the thermoelectric conversion element with the unevenness is 1.38 times larger than that obtained for the thermoelectric conversion element without the unevenness. Generally, a power generation amount P of the thermoelectric conversion element is expressed by the following equations.

$$P = \frac{X}{{( X + 1 )}^{2}} \frac{{E}^{2}}{{R}_{ss}} , X = \frac{R}{{R}_{ss}} \qquad [ Mathematical Expression 1 ]$$

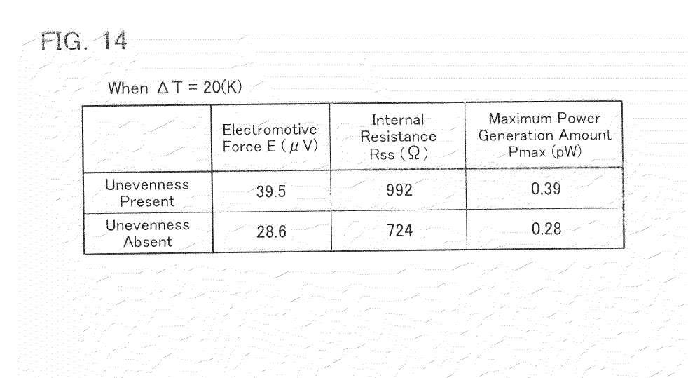

Now, P is the power generation amount, E is the thermal electromotive force, Rss is an internal resistance of the thermoelectric conversion element, and R is an external load resistance. According to the above equations, in the case that the thermal electromotive force E is constant, the power generation amount P becomes a maximum when the internal resistance Rss of the thermoelectric conversion element and the external load resistance R are equal. The thermal electromotive force E and internal resistance Rss and a maximum power generation amount Pmax when the temperature difference ΔT is 20 K for the thermoelectric conversion elements with and without the unevenness is shown in FIG. 14. The maximum power generation amount Pmax is 1.39 times larger when the unevenness is present compared to when the unevenness is absent. In this way, generated electricity density of the thermoelectric conversion element of the fourth embodiment that has the unevenness in the surface of the insulating ferromagnetic layer is increased compared to that of the planar thermoelectric conversion element without the unevenness in the surface of the insulating ferromagnetic layer of FIG. 1.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A thermoelectric conversion element, comprising:
a substrate;
an insulating ferromagnetic layer formed upwardly on the substrate and having a magnetization fixed in a certain direction;
at least one trench formed so as to extend in a direction along a surface of the insulating ferromagnetic layer; and
a nonmagnetic metal layer formed conforming to a shape of the trench, upwardly on the insulating ferromagnetic layer including on a wall surface of the trench.

2. The thermoelectric conversion element according to claim 1, wherein
the insulating ferromagnetic layer is configured to generate a spin flow in a direction perpendicular to each of surfaces of the trench, by being provided with a temperature gradient.

3. The thermoelectric conversion element according to claim 2, wherein
the nonmagnetic metal layer is configured to generate an electromotive force in a direction intersecting with the magnetization and the spin flow, by an inverse spin Hall effect of the spin flow.

4. The thermoelectric conversion element according to claim 1, wherein
a cross-sectional shape of the trench is a rectangle, a trapezoid, a V shape, a U shape, an arc, or a combination of these.

5. The thermoelectric conversion element according to claim 1, wherein
a width of the trench is 30 nm or more.

6. The thermoelectric conversion element according to claim 1, wherein
a ratio of height to width of the trench is greater than 1.

7. The thermoelectric conversion element according to claim 1, wherein
the insulating ferromagnetic layer includes any one of garnet ferrite, spinel ferrite, or hexagonal ferrite.

8. The thermoelectric conversion element according to claim 1, wherein
the nonmagnetic metal layer includes Pt, Au, Ir, Ni, Ta, W, and Cr.

9. The thermoelectric conversion element according to claim 1, wherein
the substrate is of a polyimide, polypropylene, nylon, polyester, parylene, rubber, biaxial stretching polyethylene 2,6-naphthalate, or modified polyamide.

10. The thermoelectric conversion element according to claim 1, wherein
the substrate, the insulating ferromagnetic layer, and the nonmagnetic metal layer contact each other directly.

11. A thermoelectric conversion element, comprising:
a substrate;
at least one trench formed so as to extend in a direction along a surface of the substrate;
an insulating ferromagnetic layer formed having a shape that conforms to a shape of the trench, upwardly on the surface of the substrate including on a wall surface of the trench, and having a magnetization fixed in a direction intersecting with a normal direction to the surface of the substrate; and
a nonmagnetic metal layer formed upwardly on a surface of the insulating ferromagnetic layer and formed so as to have a shape that conforms to the shape of the trench.

12. The thermoelectric conversion element according to claim 11, wherein
the insulating ferromagnetic layer is configured to generate a spin flow in a direction perpendicular to each of surfaces of the trench, by being provided with a temperature gradient.

13. The thermoelectric conversion element according to claim 12, wherein
the nonmagnetic metal layer is configured to generate an electromotive force in a direction intersecting with the magnetization and the spin flow, by an inverse spin Hall effect of the spin flow.

14. The thermoelectric conversion element according to claim 11, wherein
a cross-sectional shape of the trench is a rectangle, a trapezoid, a V shape, a U shape, an arc, or a combination of these.

15. The thermoelectric conversion element according to claim 11, wherein
a width of the trench is 30 nm or more.

16. The thermoelectric conversion element according to claim 11, wherein
a ratio of height to width of the trench is greater than 1.

17. The thermoelectric conversion element according to claim 11, wherein
the insulating ferromagnetic layer includes any one of garnet ferrite, spinel ferrite, or hexagonal ferrite.

18. The thermoelectric conversion element according to claim 11, wherein
the nonmagnetic metal layer includes Pt, Au, Ir, Ni, Ta, W, and Cr.

19. The thermoelectric conversion element according to claim 11, wherein
the substrate, the insulating ferromagnetic layer, and the nonmagnetic metal layer contact each other directly.

20. The thermoelectric conversion element according to claim 11, wherein
the trench extends along both of a first direction conforming to the surface of the substrate and a second direction intersecting with this first direction.
